(19) United States
(12) Patent Application Publication
(10) Pub. No.: US 2023/0384678 A1
(43) Pub. Date: Nov. 30, 2023

(54) Semiconductor manufacturing method

(71) Applicant: United Semiconductor (Xiamen) Co., Ltd., Xiamen (CN)

(72) Inventors: Chien-Chung Tsai, Shamen City (CN); QingZhang Zhang, Shamen City (CN); WEN YI TAN, Xiamen (CN)

(73) Assignee: United Semiconductor (Xiamen) Co., Ltd., Xiamen (CN)

(21) Appl. No.: 17/844,750

(22) Filed: Jun. 21, 2022

(30) Foreign Application Priority Data
May 26, 2022 (CN) 202210585590.3

(51) Int. Cl. G03F 7/09; G03F 7/16

(52) U.S. Cl. CPC G03F 7/091; G03F 7/162; G03F 7/168

(57) ABSTRACT

The invention provides a semiconductor manufacturing method, which comprises providing a substrate with a photoresist layer, forming a hydrophilic film on a surface of the photoresist layer by a spin coating process, and forming a top anti-reflective coating (TARC) on the surface of the hydrophilic film.

### BACKGROUND OF THE INVENTION

### 1. Field of the Invention

The invention relates to the field of semiconductor manufacturing, in particular to a method for improving the efficiency of exposure and development process and saving cost.

### 2. Description of the Prior Art

Exposure and development are quite common steps in semiconductor manufacturing. After the photoresist layer is formed on the substrate or material layer, in order to reduce the reflection of light in the subsequent exposure step, a top anti-reflective coating (TARC), such as a polymer layer, is usually formed on the surface of the photoresist layer to reduce the reflection of light in the exposure step and improve the accuracy of the exposure step. Then the top anti-reflective coating will be removed in the development step (including the step of cleaning with water). Therefore, the top anti-reflective coating is made of hydrophilic material.

However, the surface of photoresist after baking has high hydrophobicity, so when the top anti-reflective coating is formed, it is not easy to attach to the surface of photoresist. In order to form enough top anti-reflective coating on the photoresist surface, a large amount of top anti-reflective coating must be consumed. This also causes waste of materials.

### SUMMARY OF THE INVENTION

To solve the above issues, the present invention provides a semiconductor manufacturing method, which includes providing a substrate with a photoresist layer, forming a hydrophilic film on a surface of the photoresist layer by spin coating, and forming a top anti-reflective coating (TARC) on the surface of the hydrophilic film.

The invention is characterized in that after the photoresist layer is formed, a hydrophilic film is additionally formed on the surface of the photoresist layer, so that the hydrophobicity of the photoresist surface can be reduced. Therefore, in the subsequent formation of a highly hydrophilic top anti-reflective coating, the top anti-reflective coating can be attached to the hydrophilic film without directly contacting the photoresist layer. In this way, the top anti-reflective coating can be more easily attached to the hydrophilic film, which can save a lot of materials.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 show the semiconductor manufacturing method according to a preferred embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

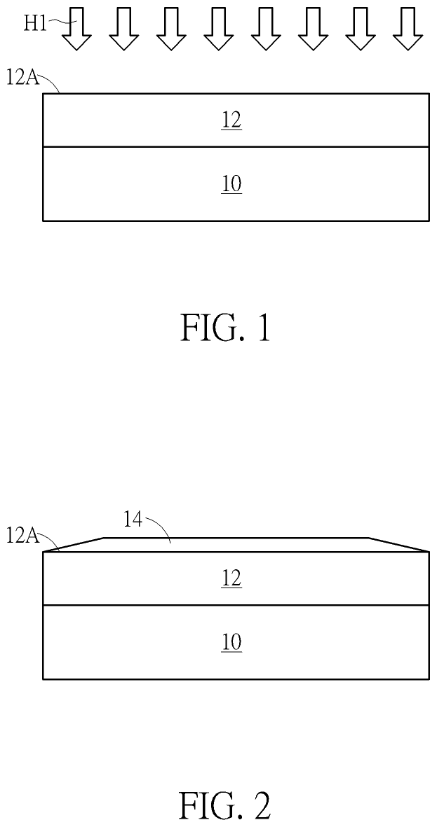

FIG. 1 to FIG. 4 show the semiconductor manufacturing method according to a preferred embodiment of the present invention. As shown in FIG. 1, firstly, a substrate 10 is provided, the substrate 10 may be a silicon substrate or a layer composed of other materials, such as dielectric layers (such as silicon oxide, silicon nitride, silicon oxynitride), metal layers, alloy layers, polymer layers, etc., which are common in semiconductor processes. The present invention is not limited to the material of the substrate 10. Then, a photoresist layer 12 is formed on the surface of the substrate 10, wherein the photoresist layer 12 is formed on the surface of the substrate 10 by a spin coating process, and then the photoresist layer 12 is heated and cured by a first baking step H1.

The surface 12A of the cured photoresist layer 12 has high hydrophobicity, that is, when pure water drops on the surface 12A of the photoresist layer 12, the water is not easy to adhere to the surface 12A, and it is easy to stay on the surface 12A like water drops. Generally speaking, the term “high hydrophobicity” here is defined as a hydrophobic surface, for example, when the water drops are on the surface, the contact angle between the water drops and the surface is greater than 90 degrees. In the definition of the present invention, if the contact angle between water droplets and the surface is greater than 160 degrees, it can be defined as a high hydrophobic surface. Relative to high hydrophobicity, if the contact angle between water droplets and the surface is less than 20 degrees, it can be defined as a hydrophilic surface. It should be noted that the above definition and contact angle of hydrophilicity and hydrophobicity are one example of the present invention, but the present invention is not limited to the actual contact angle.

In the conventional technologies, if the top anti-reflective coating (TARC) is directly formed on the surface 12A of the photoresist layer 12, since the top anti-reflective coating is also made of water-soluble material, so it is not easy to adhere to the surface with high hydrophobicity. Usually, a large amount of top anti-reflective coating material needs to be repeatedly sprayed, so that the top anti-reflective coating with sufficient thickness can be barely adhered to the surface 12A of the photoresist layer 12. As a result, materials are wasted.

Therefore, as shown in FIG. 2, the present invention additionally forms a hydrophilic film 14 on the surface 12A of the photoresist layer 12, the hydrophilic film 14 is, for example, sprayed with deionized water on the surface 12A of the photoresist layer 12, and then the water film is more evenly distributed on the surface 12A by spin coating. It is worth noting that, although deionized water is not easy to adhere to the hydrophobic surface 12A, because the cost of deionized water is lower than that of the top anti-reflective coating (TARC), a large amount of deionized water can be used for spraying and spin coating until a hydrophilic film (deionized water film) 14 is formed on the surface 12A of the photoresist layer 12.

Next, as shown in FIG. 3, a top anti-reflective coating (TARC)16 is formed on the hydrophilic film 14. As mentioned above, the top anti-reflective coating 16 is a water-soluble material, so it can be easily attached to the hydrophilic film 14. From the microscopic point of view, part of the top anti-reflective coating 16 may be dissolved in the hydrophilic film 14. Therefore, compared with the conventional technology (without forming a hydrophilic film), only a small amount of top anti-reflective coating 16 is enough to be attached to the photoresist layer 12, which can save a lot of materials. According to the experimental results of the applicant, about 30% to more than 50% of the top anti-reflective coating materials can be saved.

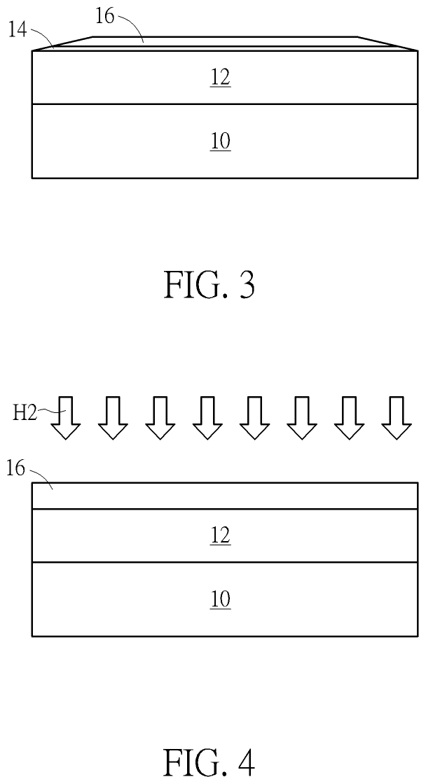

Then, as shown in FIG. 4, a second baking step H2 is performed, in which the second baking step H2 removes the hydrophilic film 14 at a high temperature and also removes moisture in the top anti-reflective coating 16. After the second baking step H2, the hydrophilic film 14 is removed, and the top anti-reflective coating 16 directly contacts the surface 12A of the photoresist layer 12.

In the next step, the photoresist layer 12 will be exposed and developed. It is worth noting that after the development process, the top anti-reflective coating 16 made of water-soluble material will be removed together, leaving the patterned photoresist layer. The related technology here belongs to the conventional technology in the field, so it will not be described in detail.

According to the above description and drawings, the present invention provides a semiconductor manufacturing method, which includes providing a substrate 10, forming a photoresist layer 12 on the substrate 10, forming a hydrophilic film 14 on a surface of the photoresist layer by a spin coating process, and forming a top anti-reflective coating (TARC) 16 on the surface of the hydrophilic film 14.

In some embodiments of the present invention, the hydrophilic membrane 14 contains deionized water.

In some embodiments of the present invention, after the photoresist layer 12 is formed, a first baking step H1 is performed to remove moisture from the surface 12A of the photoresist layer 12.

In some embodiments of the present invention, after the top anti-reflective coating 16 is formed, a second baking step H2 is performed to remove moisture in the top anti-reflective coating 16 and the hydrophilic film 14.

In some embodiments of the present invention, the surface 12A of the photoresist layer 12 is hydrophobic, and the top anti-reflective coating 16 is hydrophilic.

In some embodiments of the present invention, after the top anti-reflective coating 16 is formed, a developing step is further included, in which the top anti-reflective coating 16 is removed together in the developing step.

In some embodiments of the invention, the time of the spin coating process is 5 seconds to 30 seconds.

In some embodiments of the present invention, when the top anti-reflective coating 16 is formed, a part of the top anti-reflective coating 16 is dissolved in the hydrophilic film 14 and attached to the surface of the photoresist layer 12.

To sum up, in the present invention, before the top anti-reflective coating (TARC) is formed by spraying, a hydrophilic film (formed by a spin coating process) is formed on the baked photoresist layer. The hydrophilic film can reduce the difference of hydrophilicity and hydrophobicity between photoresist and TARC, making it easier for TARC to adhere, so that the spraying amount of TARC can be reduced, at least by 30% or even by more than 50%.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor manufacturing method, comprising:
providing a substrate, a photoresist layer is formed on the substrate;
forming a hydrophilic film on a surface of the photoresist layer by a spin coating process; and
forming a top anti-reflective coating (TARC) on the surface of the hydrophilic film.

2. The semiconductor manufacturing method according to claim 1, wherein the hydrophilic film comprises deionized water.

3. The semiconductor manufacturing method according to claim 1, wherein after the photoresist layer is formed, a first baking step is performed to remove moisture on the surface of the photoresist layer.

4. The semiconductor manufacturing method according to claim 1, wherein after the top anti-reflective coating is formed, further comprising performing a second baking step to remove moisture in the top anti-reflective coating and simultaneously remove the hydrophilic film.

5. The semiconductor manufacturing method according to claim 1, wherein the surface of the photoresist layer is hydrophobic and the top anti-reflective coating is hydrophilic.

6. The semiconductor manufacturing method according to claim 1, wherein after the top anti-reflective coating is formed, a developing step is further performed, wherein the top anti-reflective coating is removed during the developing step.

7. The semiconductor manufacturing method according to claim 1, wherein the time of the spin coating process is 5 seconds to 30 seconds.

8. The semiconductor manufacturing method according to claim 1, wherein when the top anti-reflective coating is formed, a part of the top anti-reflective coating is dissolved in the hydrophilic film and attached to the surface of the photoresist layer.
